(19) United States
(12) Patent Application Publication
(10) Pub. No.: US 2010/0193903 A1
(43) Pub. Date: Aug. 5, 2010

(54) THREE DIMENSIONAL SEMICONDUCTOR DEVICE, METHOD OF MANUFACTURING THE SAME AND ELECTRICAL CUTOFF METHOD FOR USING FUSE PATTERN OF THE SAME

(75) Inventor: Gu-Sung Kim, Gyeonggi-do (KR)

Correspondence Address: GROSSMAN, TUCKER, PERREAULT & PFLEGER, PLLC, 55 SOUTH COMMERICAL STREET, MANCHESTER, NH, 03101, US

(73) Assignee: EPWORKS CO., LTD., Gyeonggi-do (KR)

(21) Appl. No.: 12/671,280

(22) PCT Filed: Jul. 30, 2008
(86) PCT No.: PCT/KR08/04441

§ 371 Date: Jan. 29, 2010

(30) Foreign Application Priority Data
Jul. 23, 2008 (KR) 10-2008-0071526

(51) Int. Cl. H01L 23/525; H01L 21/50; H01L 21/768

(52) U.S. Cl. 257/529; 438/109; 438/17; 257/E23.15; 257/E21.499; 257/E21.596

(57) ABSTRACT

Provided is a three-dimensional semiconductor device. The three-dimensional semiconductor device includes a body in which a plurality of semiconductor chips or packages are stacked, a protective substrate configured to protect an outer layer chip or package of the body and configured to transmit a laser beam, and a fuse pattern portion having a pattern of a fuse function formed to cut off an electrical connection of a defective chip or package by the laser beam penetrating the protective substrate when at least one of the chips or packages is defective.

### TECHNICAL FIELD

The present invention relates to a three-dimensional semiconductor device, and more particularly, to a three-dimensional semiconductor device having a plurality of stacked semiconductor chips or packages for interrupting an operation of a partially defective chip or package, a method of manufacturing the same, and an electrical cutoff method using a fuse pattern of the same.

### BACKGROUND ART

The recent trend in semiconductor devices is toward high capacity, multifunction, subminiaturization, and high productivity. Accordingly, three-dimensional semiconductor technologies to which a technique of stacking a plurality of semiconductor chips or packages is applied are widely used. In the three-dimensional semiconductor technologies, a three-dimensional semiconductor device is manufactured by stacking chips or packages at a chip or wafer level and mounting the stacked chips or packages on an external connection substrate through a ball grid array method, etc.

However, when at least one chip or package is defective in a conventional three-dimensional semiconductor device, it is structurally impossible to remove only a corresponding defective chip or package, and thus the entire three-dimensional semiconductor device becomes a defective product.

As the number of stacked semiconductor chips or packages increases, the fraction of defective three-dimensional semiconductor devices increases. Since it is impossible to repair a three-dimensional semiconductor device that has been rendered defective by a defective chip or package, or to reuse normal chips and packages, all the chips and packages constituting the defective device are discarded. Accordingly, significant economic loss is incurred by degradation of semiconductor device yield.

### DISCLOSURE

### Technical Problem

The present invention provides a three-dimensional semiconductor device that can electrically cutoff a partially defective chip or package so that the entire semiconductor device product is not rendered defective.

The present invention also provides a method of manufacturing the three-dimensional semiconductor device.

The present invention also provides an electrical cutoff method using a fuse pattern of the three-dimensional semiconductor device.

The present invention is not limited to the above-mentioned objects, and those skilled in the art may clearly understand other objects from the following description.

### Technical Solution

According to an example embodiment of the present invention, a three-dimensional semiconductor device includes: a body in which a plurality of semiconductor chips or packages are stacked; a protective substrate configured to protect an outer layer chip or package of the body and configured to transmit a laser beam; and a fuse pattern portion having a pattern of a fuse function formed to cut off an electrical connection of a defective chip or package by the laser beam penetrating the protective substrate when at least one of the chips or packages is defective.

According to another example embodiment of the present invention, a method of manufacturing a three-dimensional semiconductor device includes: stacking a plurality of semiconductor chips or packages, and forming a body such that the respective chips or packages are electrically connected to through vias; stacking and forming a metal electrode electrically connected to the through vias at an upper portion of the body; forming a fuse pattern portion having a pattern of a fuse function for cutting off an electrical connection of a defective chip or package when at least one of the chips or packages is defective; and forming an outer layer protective substrate configured to transmit a laser beam at an upper portion of the fuse pattern portion.

According to still another example embodiment of the present invention, an electrical cutoff method using a fuse pattern of a three-dimensional semiconductor device includes: inspecting electrical connections and operations of respective chips or packages of the three-dimensional semiconductor device; radiating a laser beam to a fuse pattern of power, ground, and data lines electrically connected to a corresponding defective chip or package upon finding that at least one of the chips or packages is defective; and stopping an operation of the corresponding defective chip or package by enabling the laser beam to electrically cut off the fuse pattern of the corresponding defective power, ground, and data lines.

### Advantageous Effects

A three-dimensional semiconductor device of the present invention as described above has at least one of the following advantageous effects.

First, productivity can be maximized by electrically cutting off a partially defective chip or package using a fuse pattern so that the entire semiconductor device product is not rendered defective.

Second, when some data lines are defective in a three-dimensional semiconductor memory device, the defective data lines can be electrically cut off by a fuse pattern so that the entire semiconductor chip, package, etc. does not malfunction.

The present invention is not limited to the above-described advantageous effects. Those skilled in the art may clearly understand other advantageous effects from the appended claims.

### DESCRIPTION OF DRAWINGS

FIG. 1 is an isometric view schematically showing a three-dimensional semiconductor device according to an example embodiment of the present invention.

FIG. 2 is a cross-sectional view taken along line II-II of FIG. 1.

FIG. 3 is a plan view of a fuse pattern portion shown in FIG. 2.

FIG. 4 is a cross-sectional view schematically showing a three-dimensional semiconductor device according to another example embodiment of the present invention.

FIG. 5 is a cross-sectional view schematically showing a three-dimensional semiconductor device according to still another example embodiment of the present invention.

FIG. 6 is a flowchart illustrating a method of manufacturing a three-dimensional semiconductor device of the present invention.

FIG. 7 is a cross-sectional view showing a state of radiating a laser beam for electrical cutoff by a fuse pattern of the three-dimensional semiconductor device of the present invention.

FIG. 8 is a plan view showing a state of the fuse pattern in which an electrical connection of a defective chip or package is cut off by radiating the laser beam.

FIG. 9 is a flowchart illustrating an electrical cutoff method using the fuse pattern of the three-dimensional semiconductor device of the present invention.

### MODES FOR INVENTION

Advantages and features of the present invention, and methods of achieving them, will be more clearly understood by reference to the following example embodiments described in conjunction with the accompanying drawings. This invention may, however, be embodied in many different forms and should not be construed as limited to the example embodiments set forth herein. Rather, these example embodiments are provided so that this disclosure is thorough, and will fully enable those skilled in the art to embody and practice the present invention. The scope of the invention is defined by the appended claims. Throughout the drawings, each component is denoted by the same reference numeral.

Hereinafter, a three-dimensional semiconductor device, a method of manufacturing the same, and an electrical cutoff method using a fuse pattern of the same, according to example embodiments of the present invention, will be described in detail with reference to the accompanying drawings. For clarity and conciseness, descriptions of well-known functions and constructions will be omitted.

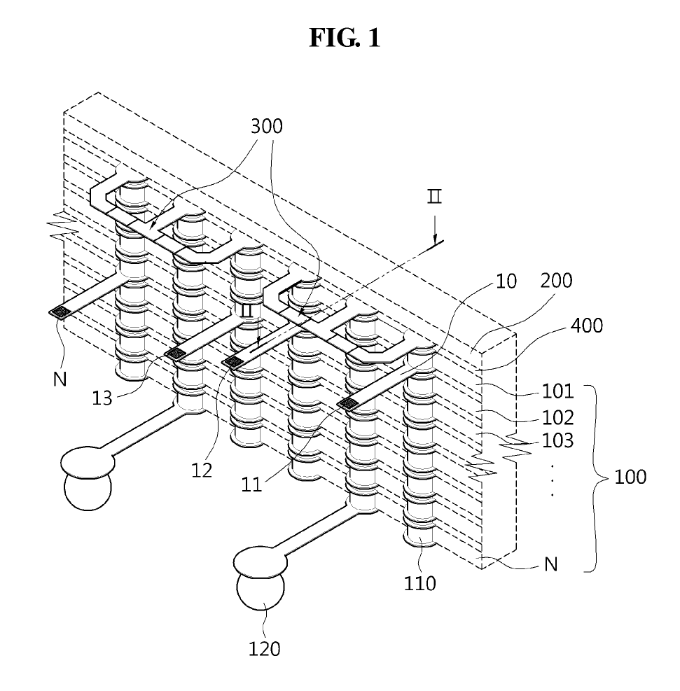

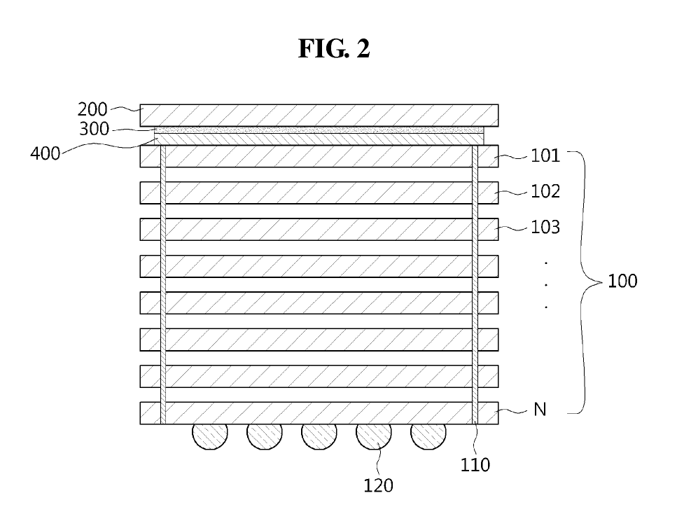

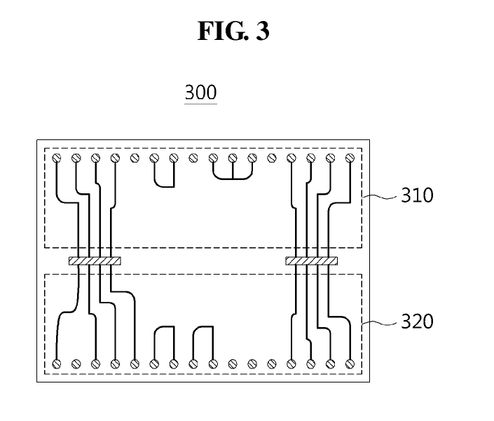

FIG. 1 is an isometric view schematically showing a three-dimensional semiconductor device according to an example embodiment of the present invention, FIG. 2 is a cross-sectional view taken along line II-II of FIG. 1, and FIG. 3 is a plan view of a fuse pattern portion shown in FIG. 2.

As shown in FIGS. 1 to 3, the three-dimensional semiconductor device according to an example embodiment of the present invention includes a body 100, a protective substrate 200, a fuse pattern portion 300, a metal electrode 400, etc.

The body 100 is formed by vertically stacking a plurality of substrates 101, 102, 103, - - - , N on which homogeneous or heterogeneous semiconductor chips or packages 11, 12, 13, - - - , N are mounted respectively. Power, ground, and data lines of the respective chips or packages 11, 12, 13, - - - , N are electrically connected to through vias 110 arranged perpendicular to the body 100 through lead pads 10.

The body 100 includes external connection terminals electrically connected to an external substrate (not shown), for example, a plurality of ball grid arrays 120, at a lowest portion.

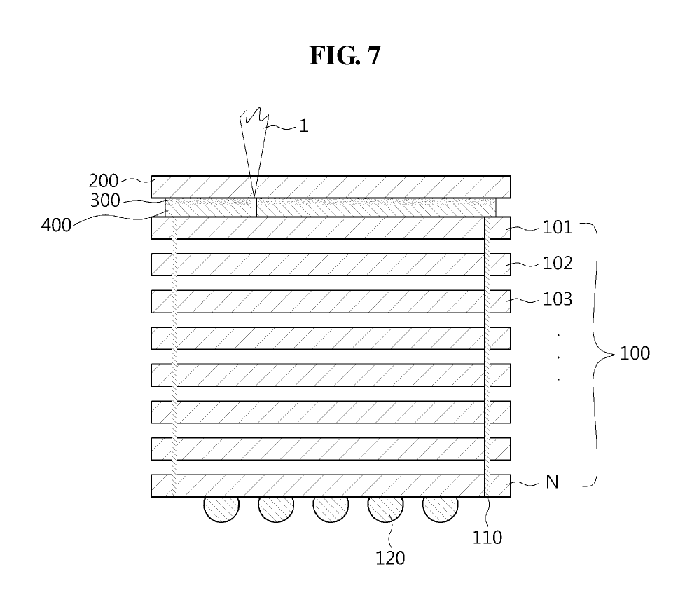

The protective substrate 200 protects an outer layer chip or package 11 of the body 100, and is a substrate of a glass system having predetermined transmittance capable of transmitting a laser beam (as indicated by reference numeral 1 of FIG. 7).

The protective substrate 200 may be joined to the body 100 by a highly polymerized compound of a polyimide or polymer series, or a metal bump.

When at least one of the chips or packages 11, 12, 13, - - - , N is defective, the fuse pattern portion 300 has a pattern of a fuse function for cutting off an electrical connection of a defective chip or package by radiating a laser beam penetrating the protective substrate 200.

The fuse pattern portion 300 includes a first fuse pattern portion 310 for forming a pattern electrically connected to external power, ground, and data lines for operation and data transmission of the chips or packages 11, 12, 13, - - - , N and a second fuse pattern portion 320 for forming a pattern electrically connected to the lead pads 10 of the respective chips or packages 11, 12, 13, - - - , N. In this example embodiment, the first fuse pattern portion 310 and the second fuse pattern portion 320 form symmetrical patterns as shown in FIG. 3, but the present invention is not limited to such patterns. Alternatively, asymmetrical patterns may be formed.

The fuse pattern portion 300 is formed at an upper portion of the outer layer chip or package 11 of the body 100. The patterns of the fuse pattern portion 300 may be electrically connected to the respective chips or packages 11, 12, 13, - - - , N through the metal electrode 400 to be described later.

It is preferable for the fuse pattern portion 300 to form patterns using a conductive material containing at least one of Cr/Cu, Ti/Cu, Cr/Cu/Ni, and Ti/Cu/Ni.

To be electrically connected to the through vias 110, the metal electrode 400 is stacked on the entire surface of the outer layer of the body 100.

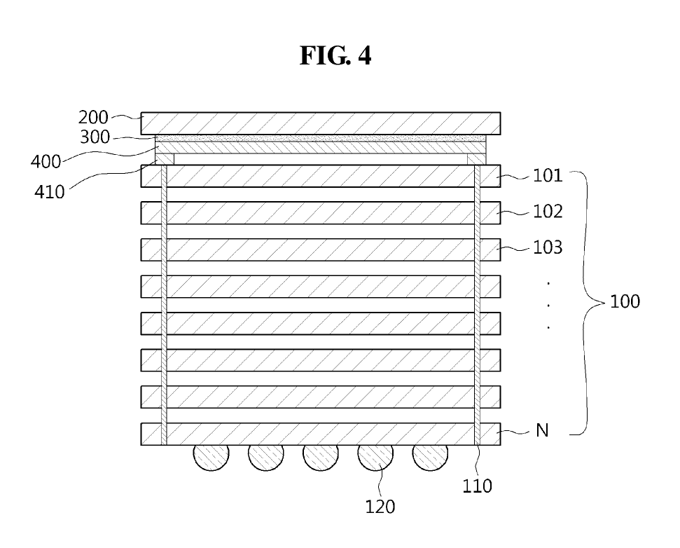

FIG. 4 is a cross-sectional view schematically showing a three-dimensional semiconductor device according to another example embodiment of the present invention.

As shown in FIG. 4, the three-dimensional semiconductor device according to another example embodiment of the present invention includes a body 110, a protective substrate 120, a fuse pattern portion 300, a metal electrode 400, etc., and is the same as the three-dimensional semiconductor device described with reference to FIGS. 1 to 3, except that the metal electrode 400 is connected to through vias 110 by a bridge electrode 410. Accordingly, the same reference numerals are assigned to the same functional elements as in the example embodiment. Descriptions of the same functional elements are omitted.

The bridge electrode 410 is provided on an upper surface of the through vias 110 and connects the through vias 110 to the metal electrode 400 in a bridge form. It is preferable to form the bridge electrode 410 of the same conductive material as the metal electrode 400.

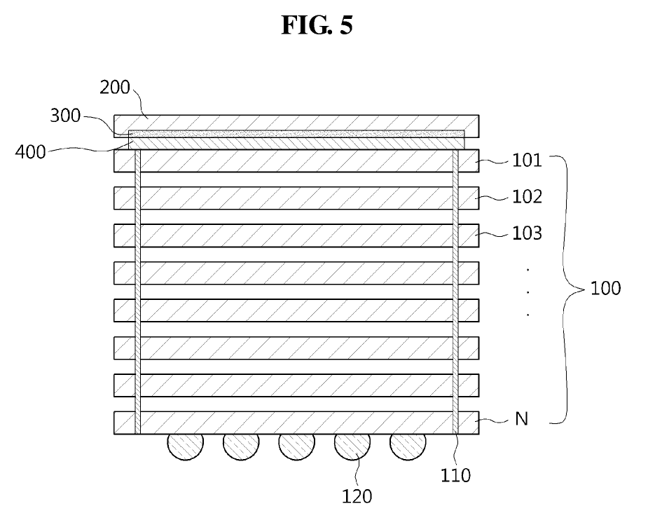

FIG. 5 is a cross-sectional view schematically showing a three-dimensional semiconductor device according to still another example embodiment of the present invention.

As shown in FIG. 5, the three-dimensional semiconductor device according to still another example embodiment of the present invention includes a body 110, a protective substrate 120, a fuse pattern portion 300, a metal electrode 400, etc., and is the same as the three-dimensional semiconductor device described with reference to FIGS. 1 to 3, except that the metal electrode 400 is formed in the protective substrate 120. Accordingly, the same reference numerals are assigned to the same functional elements as in the example embodiment. Descriptions of the same functional elements are omitted.

The fuse pattern portion 300 is integratedly formed with the protective substrate 200, and preferably formed in a lowest layer of the protective substrate 200. The fuse pattern portion 300 has patterns electrically connected to power, ground, and data lines for operation and data transmission of the respective chips or packages 11, 12, 13, - - - , N, as shown in FIG. 3.

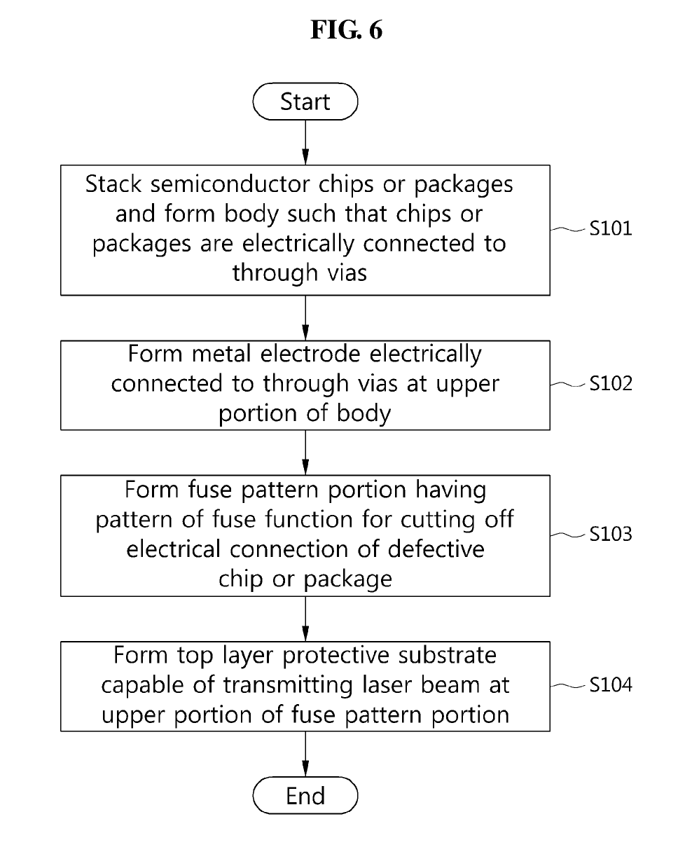

FIG. 6 is a flowchart illustrating a method of manufacturing a three-dimensional semiconductor device of the present invention.

In the method of manufacturing a three-dimensional semiconductor device of the present invention shown in FIG. 6, first, substrates 101, 102, 103, - - - , N on which semiconductor chips or packages 11, 12, 13, - - - , N are respectively mounted are vertically stacked and form a body 100, such that the respective chips or packages 11, 12, 13, - - - , N are electrically connected to vertically arranged through vias 110 (step S101).

Next, a metal electrode 400 electrically connected to the through vias 110 is stacked at an upper portion of the body 100 (step S102).

Next, when at least one of the chips or packages 11, 12, 13, - - - , N is defective, the fuse pattern portion 300 having a pattern of a fuse function for cutting off an electrical connection of the defective chip or package is formed (step S103). It is preferable to form the fuse pattern portion 300 integrated with the lowest layer of a protective substrate 200 or to form the fuse pattern portion 300 at the upper portion of the outer layer chip or package 101 of the body 100, particularly, at the upper portion of the metal electrode 400. Here, the fuse pattern portion 300 may include a first fuse pattern portion 310 electrically connected to power, ground, and data lines for operation and data transmission of the chips or packages 11, 12, 13, - - - , N, and a second fuse pattern portion 320 electrically connected to lead pads 10 of the respective chips or packages 11, 12, 13, - - - , N.

At last, the outer layer protective substrate 200 capable of transmitting a laser beam 1 is formed at the upper portion of the fuse pattern portion 300 (step S104).

Hereinafter, an electrical cutoff method using the fuse pattern of the three-dimensional semiconductor device of the present invention will be described in detail with reference to FIGS. 7 to 9.

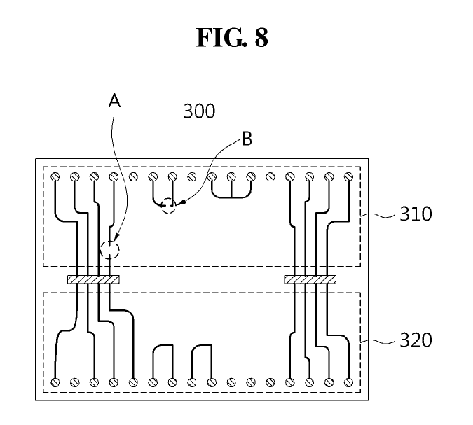

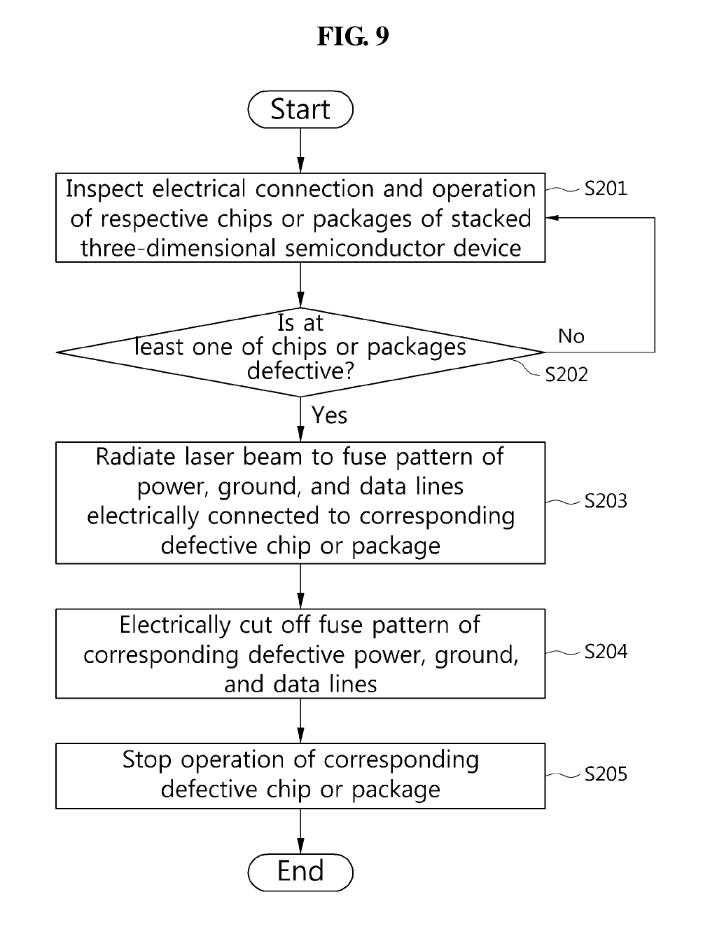

FIG. 7 is a cross-sectional view showing a state of radiating a laser beam for electrical cutoff by a fuse pattern of the three-dimensional semiconductor device of the present invention, FIG. 8 is a plan view showing a state of the fuse pattern in which an electrical connection of a defective chip or package is cut off by radiating the laser beam, and FIG. 9 is a flowchart illustrating an electrical cutoff method using the fuse pattern of the three-dimensional semiconductor device of the present invention.

In the electrical cutoff method using the fuse pattern of the three-dimensional semiconductor device of the present invention as shown in FIGS. 7 to 9, electrical connections and operations of the respective chips or packages 11, 12, 13, - - - , N of the three-dimensional semiconductor device are first inspected (step S201). An X-ray or other known error check and correction test method may be used as an inspection method.

Upon finding that at least one of the chips or packages 11, 12, 13, - - - , N is defective (step S202), a laser beam is radiated to a fuse pattern of power, ground, and data lines electrically connected to a corresponding defective chip or package (step S203). It is preferred that the laser beam 1 is a CO₂ or ND:YAG (Neodymium-Doped Yttrium Aluminum Garnet) laser. On the other hand, upon finding that no chip or package is defective, electrical connections and operations of the respective chips or packages 11, 12, 13, - - - , N are repeatedly inspected.

Next, the laser beam 1 performs an electrical cutoff operation on the fuse pattern of corresponding defective power, ground, and data lines (step S204), and an operation of a defective chip or package corresponding to electrical cutoff fuse pattern regions (“A” and “B” of FIG. 8) is stopped (step S205).

That is, the electrical cutoff method using the fuse pattern eliminates defective operations such as electrical disconnection and malfunction caused by a defective chip or package in the three-dimensional semiconductor device on which the chips or packages 11, 12, 13, - - - , N are stacked, thereby preventing the entire semiconductor device product from being rendered defective and maximizing productivity. When some data lines are defective in a three-dimensional semiconductor memory device, malfunction of the entire semiconductor chip, package, etc. can be eliminated by electrical cutoff of corresponding defective data lines by the fuse pattern.

Although example embodiments have been described herein with reference to the accompanying drawings, it will be understood by those skilled in the art that the present invention may be subject to many modifications and changes without departing from the spirit or essential characteristics thereof. The above-described example embodiments should be considered in all aspects as illustrative and not restrictive of the scope of the present invention as defined by the appended claims. Therefore, the present invention is not limited to the above-described embodiments, but is defined by the following claims, along with their full scope of equivalents.

### INDUSTRIAL APPLICABILITY

A three-dimensional semiconductor device, a method of manufacturing the same, and an electrical cutoff method using a fuse pattern of the same, according to the present invention, can be widely used in three-dimensional semiconductor technologies to which a technique of stacking a plurality of semiconductor chips or packages is applied for high capacity, multifunction, subminiaturization, and high productivity.

1. A three-dimensional semiconductor device comprising:
a body in which a plurality of semiconductor chips or packages are stacked;
a protective substrate configured to protect an outer layer chip or package of the body and configured to transmit a laser beam; and
a fuse pattern portion having a pattern of a fuse function formed to cut off an electrical connection of a defective chip or package by the laser beam penetrating the protective substrate when at least one of the chips or packages is defective.

2. The three-dimensional semiconductor device of claim 1, wherein the fuse pattern portion includes:
a first fuse pattern portion having a pattern electrically connected to power, ground, and data lines for operation and data transmission of the chips or packages; and
a second fuse pattern portion having a pattern electrically connected to lead pads of the respective chips or packages in the first fuse pattern portion.

3. The three-dimensional semiconductor device of claim 1, wherein the fuse pattern portion is formed at an upper portion of an outer layer chip or package of the body.

4. The three-dimensional semiconductor device of claim 1, wherein the fuse pattern portion is formed in the protective substrate.

5. The three-dimensional semiconductor device of claim 1, wherein the pattern of the fuse pattern portion is electrically connected to the chips or packages through a metal electrode formed at an upper portion of the body.

6. The three-dimensional semiconductor device of claim 1, wherein the pattern of the fuse pattern portion is formed of a conductive material containing Cr and Cu.

7. The three-dimensional semiconductor device of claim 1, wherein the pattern of the fuse pattern portion is formed of a conductive material containing Ti and Cu.

8. The three-dimensional semiconductor device of claim 1, wherein the pattern of the fuse pattern portion is formed of a conductive material containing Cr, Cu, and Ni.

9. The three-dimensional semiconductor device of claim 1, wherein the pattern of the fuse pattern portion is formed of a conductive material containing Ti, Cu, and Ni.

10. The three-dimensional semiconductor device of claim 3, wherein the protective substrate is joined to the body by a highly polymerized compound of a polyimide or polymer series.

11. The three-dimensional semiconductor device of claim 4, wherein the protective substrate is joined to the body by a metal bump.

12. A method of manufacturing a three-dimensional semiconductor device, comprising:
(a) stacking a plurality of semiconductor chips or packages, and forming a body such that the respective chips or packages are electrically connected to through vias;
(b) stacking and forming a metal electrode electrically connected to the through vias at an upper portion of the body;
(c) forming a fuse pattern portion having a pattern of a fuse function for cutting off an electrical connection of a defective chip or package when at least one of the chips or packages is defective; and
(d) forming an outer layer protective substrate configured to transmit a laser beam at an upper portion of the fuse pattern portion.

13. The method of claim 12, wherein step (c) includes:
(c1) forming a first fuse pattern portion electrically connected to power, ground, and data lines for operation and data transmission of the chips or packages; and
(c2) forming a second fuse pattern portion electrically connected to lead pads of the respective chips or packages in the first fuse pattern portion.

14. The method of claim 12, wherein step (c) includes:
forming the fuse pattern portion to be integrated with a lowest layer of the protective substrate or forming the fuse pattern portion at an upper portion of the metal electrode.

15. An electrical cutoff method using a fuse pattern of a three-dimensional semiconductor device, comprising:
inspecting electrical connections and operations of respective chips or packages of the three-dimensional semiconductor device;
radiating a laser beam to a fuse pattern of power, ground, and data lines electrically connected to a corresponding defective chip or package upon finding that at least one of the chips or packages is defective; and
stopping an operation of the corresponding defective chip or package by enabling the laser beam to electrically cut off the fuse pattern of the corresponding defective power, ground, and data lines.
